(19) United States
(12) Patent Application Publication
(10) Pub. No.: US 2026/0282555 A1
(43) Pub. Date: Sep. 17, 2026

(54) CIRCUITS HAVING MULTIPLE CELL HEIGHTS WITH TRANSITION REGIONS

(71) Applicant: INTERNATIONAL BUSINESS MACHINES CORPORATION, Armonk, NY (US)

(72) Inventors: Reinaldo Vega, Mahopac, NY (US); Ryan Kosciolek, Albany, NY (US); Mahender Kumar, Clifton Park, NY (US); Ruilong Xie, Niskayuna, NY (US); Albert Manhee Chu, Nashua, NH (US); Charles Nicholas Perez, Burlington, VT (US); Jason J. Stuffle, Burlington, VT (US); Abhishek Anand, Albany, NY (US)

(21) Appl. No.: 19/081,381

(22) Filed: Mar. 17, 2025

(51) Int. Cl. H10D 89/10

(52) U.S. Cl. CPC H10D 89/10

(57) ABSTRACT

An integrated circuit includes a first cell of a first cell height having a first feature and a second cell of a second cell height having a second feature corresponding to the first feature. The first cell height is greater than the second cell height. A transition region borders the first cell and the second cell. The transition region includes a change in dimension between the first feature and the second feature.

### BACKGROUND

The present invention generally relates to semiconductor devices and processing methods, and more particularly to integrated circuit design and fabrication incorporating cells of different heights and transition regions between such cells.

Integrated circuit design includes the arrangement and configuration of standard cells, which are pre-designed circuit elements that can be combined to create more complex circuits. Traditionally, standard cells within a given design have often been constrained to a uniform height, which can simplify layout and manufacturing processes. However, as integrated circuit designs become more sophisticated, alternative approaches that allow for greater flexibility in cell arrangement and utilization of chip area are needed. Managing transitions between cells requires careful consideration of various factors, including electrical connectivity, signal integrity, and manufacturability.

### SUMMARY

In accordance with an embodiment of the present invention, an integrated circuit includes a first cell of a first cell height having a first feature and a second cell of a second cell height having a second feature corresponding to the first feature. The first cell height is greater than the second cell height. A transition region borders the first cell and the second cell. The transition region includes a change in dimension between the first feature and the second feature.

In accordance with another embodiment of the present invention, an integrated circuit includes a first cell of a first cell height having a first active region width, and a second cell of a second cell height having a second active region width. The first cell height is greater than the second cell height. A transition region borders the first cell and the second cell. The transition region at least partially includes a non-rectangular transition shape to transition a change in dimension between the first active region width and the second active region width.

In accordance with another embodiment of the present invention, an integrated circuit includes a first cell of a first cell height having a first feature; a second cell of a second cell height having a second feature, the first cell height being greater than the second cell height; and a third cell having a third feature. A transition region borders the first cell, the second cell and the third cell. The transition region at least partially includes transition shapes to transition a change in dimension between at least two of the first feature, the second feature and the third feature.

In accordance with another embodiment of the present invention, a method of forming an integrated circuit includes forming a first cell of a first cell height having a first feature; forming a second cell of a second cell height having a second feature, the first cell height being greater than the second cell height; and forming a transition region bordering the first cell and the second cell, the transition region at least partially including a transition shape to transition a change in dimension between the first feature and the second feature. Forming the first cell can include forming the first cell with a first cell length, and forming the second cell can include forming the second cell with a second cell length, the first cell length being unequal to the second cell length. The first feature can be a first active region width, and the second feature can be a second active region width. The first feature can be a first gate pitch, and the second feature can be a second gate pitch. The first feature can be a first metal line pitch, and the second feature can be a second metal line pitch. The transition region can include a non-rectangular transition shape. A diffusion break can be formed within the transition region. The transition region can include a transition region formed from a backside of the integrated circuit. At least one of the first cell or the second cell can be connected to a backside metallization layer. The transition region can span multiple cells of different cell heights.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 is a layout view of an integrated circuit showing cells of different cell height bordering a transition region on east/west sides of the transition region, in accordance with an embodiment of the present invention;

FIG. 2 is a layout view of an integrated circuit showing cells of different cell height bordering a transition region on east/west sides of the transition region with one cell overlapping or impinging on the transition region, in accordance with an embodiment of the present invention;

FIG. 3 is a layout view of an integrated circuit showing cells of different cell height bordering a transition region on east/west sides of the transition region, in accordance with an embodiment of the present invention;

FIG. 4 is a layout view of an integrated circuit showing multiple different cells having different cell heights bordering a transition region on east/west sides of the transition region, in accordance with an embodiment of the present invention;

FIG. 5 is a layout view of an integrated circuit showing cells of different cell height bordering a transition region on north/south sides of the transition region, in accordance with an embodiment of the present invention;

FIG. 6 is a layout view of an integrated circuit showing cells of different cell height bordering a transition region on north/south sides of the transition region with one cell overlapping or impinging on the transition region, in accordance with an embodiment of the present invention;

FIG. 7 is a layout view of an integrated circuit showing cells of different cell height bordering a transition region on north/south sides of the transition region, in accordance with an embodiment of the present invention;

FIG. 8 is a layout view of an integrated circuit showing multiple different cells having different cell heights bordering a transition region on north/south sides of the transition region, in accordance with an embodiment of the present invention;

FIG. 9 is a layout view of an integrated circuit showing multiple different cells having different cell heights bordering a transition region on north/south sides of the transition region and on east/west sides of some of the cells, in accordance with an embodiment of the present invention;

FIG. 10 is a layout view of the integrated circuit showing active regions as features transitioned between the cells of different cell height bordering the transition region on the east/west sides of the transition region, in accordance with an embodiment of the present invention;

FIG. 11 is a layout view of the integrated circuit showing active regions as features transitioned between the cells of different cell height bordering the transition region on the east/west sides of the transition region with one cell overlapping or impinging on the transition region, in accordance with an embodiment of the present invention;

FIG. 12 is a layout view of the integrated circuit showing active regions as features transitioned between the cells of different cell height bordering a transition region on east/west sides of the transition region, in accordance with an embodiment of the present invention;

FIG. 13 is a layout view of the integrated circuit showing active regions as features transitioned between multiple different cells having different cell heights bordering a transition region on east/west sides of the transition region, in accordance with an embodiment of the present invention;

FIG. 14 is a layout view of the integrated circuit showing gate line pitch as features transitioned between the cells of different cell height bordering the transition region on the east/west sides of the transition region, in accordance with an embodiment of the present invention;

FIG. 15 is a layout view of the integrated circuit showing gate line pitch as features transitioned between the cells of different cell height bordering the transition region on the east/west sides of the transition region with one cell overlapping or impinging on the transition region, in accordance with an embodiment of the present invention;

FIG. 16 is a layout view of the integrated circuit showing gate line pitch as features transitioned between the cells of different cell height bordering a transition region on east/west sides of the transition region, in accordance with an embodiment of the present invention;

FIG. 17 is a layout view of the integrated circuit showing gate line pitch as features transitioned between multiple different cells having different cell heights bordering a transition region on east/west sides of the transition region, in accordance with an embodiment of the present invention;

FIG. 18 is a layout view of the integrated circuit showing a gate in the transition region that can include a different gate line pitch between the cells of different cell height bordering a transition region on east/west sides of the transition region, in accordance with an embodiment of the present invention;

FIG. 19 is a layout view of the integrated circuit showing metal line pitch as features transitioned between the cells of different cell height bordering the transition region on the east/west sides of the transition region, in accordance with an embodiment of the present invention;

FIG. 20 is a layout view of the integrated circuit showing metal line pitch as features transitioned between the cells of different cell height bordering the transition region on the east/west sides of the transition region with one cell overlapping or impinging on the transition region, in accordance with an embodiment of the present invention;

FIG. 21 is a layout view of the integrated circuit showing metal line pitch as features transitioned between the cells of different cell height bordering a transition region on east/west sides of the transition region, in accordance with an embodiment of the present invention;

FIG. 22 is a layout view of the integrated circuit showing metal line pitch as features transitioned between multiple different cells having different cell heights bordering a transition region on east/west sides of the transition region, in accordance with an embodiment of the present invention;

FIG. 23 is a layout view of the integrated circuit showing a diffusion break formed in a transition region, in accordance with an embodiment of the present invention; and

FIG. 24 is a cross-sectional view of the integrated circuit showing a vertical transition region formed between cells and having a cell connecting to a backside interconnect layer, in accordance with an embodiment of the present invention.

### DETAILED DESCRIPTION

In accordance with embodiments of the present invention, devices and methods are described which include integrated circuits incorporating multiple cell heights and transition regions. In some embodiments, integrated circuits can include cells of different heights arranged in various configurations. These cells may be designed to accommodate different functional requirements or performance characteristics within a single integrated circuit design. Transition regions can be implemented between cells of different heights. These transition regions may serve to manage the interface between cells with varying dimensions or features. The transition regions can include changes in dimensions or characteristics of certain features between neighboring cells.

In an embodiment, at least two cells with different cell heights border a transition region on opposite sides of the transition region. The transition region includes a change in feature dimension between both cells. The transition region can include a partial or full transition between features in the at least two cells. The feature can include a diffusion or active region that transitions between the at least two cells. Other features can include gates, metal lines, etc. The transition region can be formed vertically (through a thickness of a semiconductor device), e.g., from a top side or backside of the semiconductor device. The transition region can be rectangular or include a non-rectangular shape. In an embodiment, the transition region can include at least one diffusion break.

In an embodiment, a first cell of a first cell height includes a first feature and a second cell of a second cell height includes a second feature corresponding to the first feature. The first height can be greater than the second cell height, and the first and second cell border a common transition region therebetween. The transition region at least partially contains a change in dimension between the first feature and the second feature.

The features can include the following. The first cell can have a first cell length (e.g., orthogonal to the cell height), and the second cell can have a second cell length, the first cell length being unequal to the second cell length. The first feature can include a first active region width, and the second feature can include a second active region width. The first feature can include a first active region thickness, and the second feature can include a second active region thickness. The first feature can include a first gate pitch, and the second feature can include a second gate pitch. The first feature can include a first metallization pitch, and the second feature can include a second metallization pitch. The first feature can include a first active region thickness, and the second feature can include a second active region thickness.

The transition region can be disposed between boundaries of the first and second cells (e.g., east and west (side to side) cell boundaries or north and south (top to bottom) boundaries when viewing a layout view). In a 3D-stacked arrangement of cells, the transition region can be disposed along a frontside of the first cell and a backside of the second cell. The transition region can be non-rectangular in shape. The transition region can include at least one diffusion break. The transition region can be formed from a frontside or backside of the semiconductor device (e.g., a vertical transition).

In other embodiments, at least one of the first cell or second cell is connected to a backside metallization layer.

The cell height can be defined as a distance between outer edges of a complementary set of active regions. The complementary set of active regions can be stacked three dimensionally (3D).

The cell height can be defined as a distance between a first center point between two first common polarity active regions and a second center point between two second common polarity active regions. The cell height can be defined as a distance between center points of outermost metal tracks on opposing ends of the cell, the metal tracks existing on a metal layer on a frontside of the cell. The cell height can be defined as a distance between center points of outermost metal tracks on opposing ends of the cell, the metal tracks existing on a metal layer on a backside of the cell. The cell height can be defined as a distance between center points of outermost metal tracks on opposing ends of the cell, the metal tracks existing in between a first device level and a second device level in a 3D-stacked cell.

The use of multiple cell heights and transition regions in integrated circuit design provides flexibility in layout and functionality. This approach permits optimization of circuit performance, power consumption, or area utilization in different portions of the integrated circuit. In some embodiments, a combination of varied cell heights and transition regions can enable more efficient use of available chip area while maintaining desired or improved circuit functionality.

Integrated circuits in accordance with the present embodiments are applicable in a wide range of electronic devices and systems. The approach of using multiple cell heights with transition regions may be adaptable to various semiconductor manufacturing processes and design methodologies.

Cells with different heights can be utilized to accommodate various functional requirements and optimize circuit performance. Cell height may be defined as the distance between outer edges of a complementary set of active regions. This definition may be particularly relevant for standard cell designs where the active regions form the core functional elements of the cell. Alternatively, the cell height may be defined as the distance between a first center point between two first common polarity active regions and a second center point between two second common polarity active regions. This approach may provide a more precise measurement of cell height, especially in designs where the active regions are not perfectly aligned or have varying widths.

In some embodiments, the cell height may be defined based on metal tracks. For example, the cell height may be defined as the distance between the center points of outermost metal tracks on opposing ends of the cell, where the metal tracks exist on a metal layer on a frontside of the cell. This definition may be useful in designs where the metal routing is an important factor in determining cell dimensions. Similarly, the cell height may be defined as the distance between the center points of the outermost metal tracks on opposing ends of the cell, where the metal tracks exist on a metal layer on the backside of the cell. This approach may be particularly relevant for designs utilizing backside metallization for power distribution or signal routing.

In advanced three-dimensional integrated circuit designs, the cell height may be defined as the distance between the center points of the outermost metal tracks on opposing ends of the cell, where the metal tracks exist in between a first device level and a second device level in a 3D-stacked cell. This definition accounts for the vertical stacking of multiple device layers and the interconnecting metal layers between them.

The use of cells with different heights in an integrated circuit design can offer several advantages. For example, taller cells may accommodate more complex logic functions or provide improved drive strength, while shorter cells may be used for simpler functions or in areas where area efficiency is prioritized. By combining cells of varying heights, designers may optimize the overall circuit layout for performance, power consumption, and area utilization. In some cases, cells with different heights may be arranged in a mixed-height configuration within the same row or across multiple rows of the integrated circuit layout. In an extreme example, a discontinuity in north/south cell boundaries in the east/west direction can lead to a complete elimination of a circuit row altogether, as the cells may be placed almost completely arbitrarily. This approach may allow for greater flexibility in circuit design and may enable more efficient use of the available chip area.

The specific implementation of cells with different heights can depend on various factors, including the target technology node, design rules, and performance requirements of the integrated circuit. In integrated circuit designs incorporating cells of different heights, transition regions may be implemented to manage the interface between neighboring cells with varying dimensions or features. These transition regions serve as intermediary areas that accommodate the differences in cell heights and other characteristics.

Transition regions can exist along boundaries between cells. In some embodiments, a transition region may be positioned along east/west boundaries of adjacent cells with different heights. This configuration permits horizontal transitions between cells, which may be particularly useful in designs where cells are arranged in rows. In other embodiments, transition regions may exist along north/south boundaries of cells with different heights. This arrangement facilitates vertical transitions between cells, which can be beneficial in designs where cells are stacked or arranged in columns. Transition regions can also be implemented along a frontside of one cell and a backside of an adjacent cell.

The shape of transition regions may vary depending on the specific design requirements and the characteristics of the adjacent cells. In some cases, transition regions may be non-rectangular, allowing for more complex interfaces between cells of different heights. This non-rectangular shape may help accommodate varying feature sizes or densities between cells.

Transition regions may incorporate specific features to manage the interface between cells. For example, a transition region can include at least one diffusion break. Diffusion breaks can assist in isolating active regions between cells, preventing unwanted electrical interactions and maintaining proper device functionality.

In some processes, transition regions may be formed from a backside of the integrated circuit. This approach can allow for greater flexibility in managing cell interfaces and can enable more efficient use of chip area. Backside formation of transition regions may be particularly relevant in designs utilizing through-silicon vias (TSVs) or other advanced packaging technologies. The specific implementation of transition regions can depend on the target technology node, design rules, performance requirements of the integrated circuit, etc.

Transition regions in accordance with embodiments of the present invention can enable the integration of cells with different heights within a single integrated circuit design. By providing a flexible interface between cells, these regions may contribute to improved circuit performance, power efficiency, and area utilization.

In integrated circuit designs incorporating cells of different heights, features within the cells and transition regions can differ to accommodate the height variations and optimize circuit performance. These features may include active region widths, gate pitches, metallization pitches, and other characteristics.

Active region widths can vary between cells of different heights. In some cases, taller cells may incorporate wider active regions to accommodate more complex logic functions or provide higher drive strength. Conversely, shorter cells may utilize narrower active regions to optimize area efficiency. The transition region between cells of different heights can include a gradual change in active region width to smoothly connect the neighboring cells.

Gate pitches may also differ between cells of varying heights. Taller cells may employ larger gate pitches to allow for larger source/drain contacts or improved electrostatic control (e.g., larger gate length). Shorter cells may use tighter gate pitches to maximize transistor density. The transition region may incorporate a gradual change in gate pitch to bridge the difference between adjacent cells.

Metallization pitches can vary across cells of different heights and within transition regions. In some cases, taller cells may utilize wider metal pitches to accommodate higher current densities or more complex routing requirements. Shorter cells may employ tighter metal pitches to optimize area utilization. The transition region may contain a gradual change in metallization pitch to ensure proper connectivity between cells.

In some embodiments, cells may be connected to backside metallization layers. This approach can permit improved power distribution or signal routing, particularly in advanced packaging technologies. In some cases, at least one of the cells with different heights may be connected to a backside metallization layer. The transition region may facilitate the connection between cells and the backside metallization, to incorporate vertical interconnects or other structures.

Transition regions can include gradual changes in different features, such as, e.g., active region widths or thicknesses, gate pitches, metallization pitches, etc.

In some cases, the interaction between cells of different heights and transition regions can enable more efficient implementation of mixed-signal circuits. Analog components, which may require taller cells with specific feature sizes, may be integrated alongside digital logic implemented in shorter cells. Transition regions may manage the interface between these different circuit domains, potentially improving overall system performance and reducing the need for separate analog and digital chips. The combination of cells with different heights and transition regions may also facilitate more effective clock distribution in the integrated circuit. Taller cells may accommodate wider clock tracks or specialized clock buffers, while shorter cells may use more compact clock distribution schemes. Transition regions may manage the interface between these different clock domains, potentially improving overall timing performance and reducing clock skew.

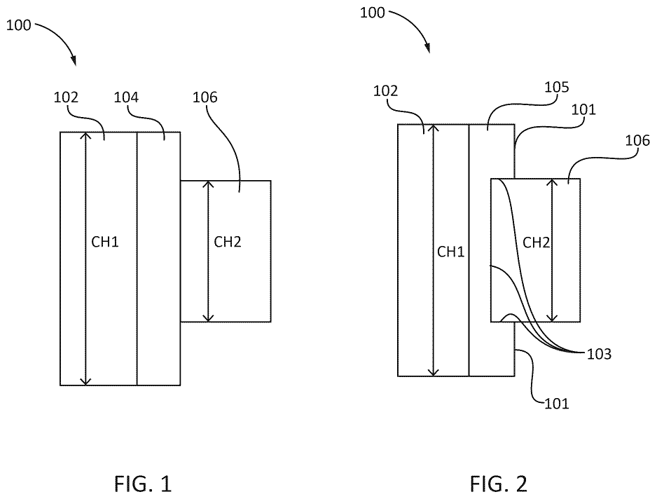

Referring now to the drawings in which like numerals represent the same or similar elements and initially to FIG. 1, devices and methods for manufacturing an integrated circuit 100 on a semiconductor device are shown in accordance with embodiments of the present invention. The integrated circuit 100 includes a plurality of cells that are configured to be placed in a manner that optimizes chip area, performance and any number of other parameters. A cell 102 includes a cell height CH1. A transition region 104 is adjacent to and borders cell 102. In this embodiment, the cell 102 and the transition region 104 share the cell height CH1 dimension. A cell 106 also borders the transition region 104 on a side opposite the cell 102. The cell 106 includes a different cell height CH2 that is not equal to CH1 of cell 102.

The transition region 104 can provide a transition between features of the cell 102 and the cell 106. This can include transitioning geometric shapes of the features to permit for size or performance differences between the cell 102 and cell 106. The cell 106 can be centered relative to cell 102 or be located at any position along the boundary of the transition region 104. Here, the transition region 104 is rectangular in shape.

Referring to FIG. 2, the integrated circuit 100 includes the cell 102 with cell height CH1. A transition region 105 is adjacent to and borders cell 102. In this embodiment, the cell 102 and the transition region 104 share the cell height CH1 dimension. A cell 106 impinges on the transition region 104 and includes an extended border 103 on a side opposite the cell 102. The cell 106 includes a different cell height CH2 that is not equal to CH1 of cell 102.

The transition region 104 can provide a transition between features of the cell 102 and the cell 106. This can include transitioning geometric shapes of the features to permit for size or performance differences between the cell 102 and cell 106 through any side of the extended border 103. The cell 106 can be centered relative to cell 102 or be located at any position along the boundary of the transition region 104. Here, the transition region 104 is non-rectangular in shape.

Adjacent cells (not shown), e.g., on a north side and/or south side of the cell 106 can impinge upon the transition region 104 in a way similar to cell 106 or align with an outer border 101 of the transition region 105 (in a similar manner as cell 106 to transition region 104 in FIG. 1).

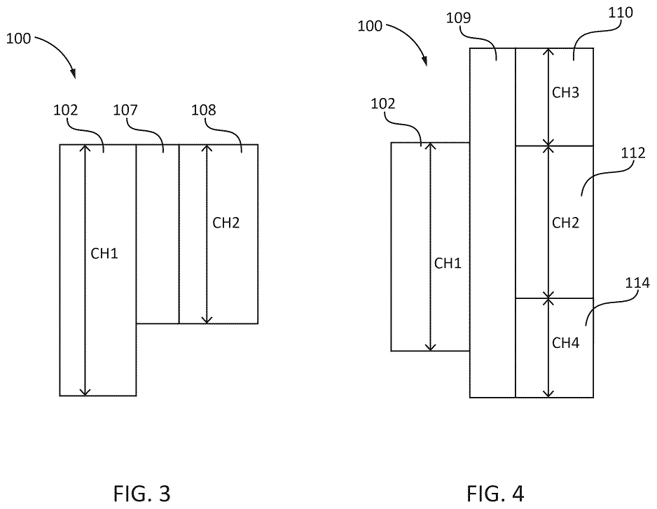

Referring to FIG. 3, the integrated circuit 100 includes a plurality of cells that are configured to be placed in a manner that optimizes chip area, performance and any number of other parameters. The cell 102 includes a cell height CH1. A transition region 107 is adjacent to and partially borders cell 102. A cell 108 also borders the transition region 107 on a side opposite the cell 102. In this embodiment, the cell 108 and the transition region 104 share the cell height CH2 dimension. Cell height CH2 of cell 108 is not equal to CH1 of cell 102.

The transition region 107 can provide a transition between features of the cell 102 and the cell 108. This can include transitioning geometric shapes of the features to permit for size or performance differences between the cell 102 and cell 108. The cell 108 can be aligned on a north (or south) end or be centered relative to cell 102 or be located at any position along the boundary of the transition region 107. Here, the transition region 107 is rectangular in shape.

Referring to FIG. 4, the integrated circuit 100 includes the cell 102 with cell height CH1. A transition region 109 is adjacent to and borders cell 102. In this embodiment, the cell 102 and the transition region 109 do not share the cell height CH1 dimension. Instead, adjacent cells 110, 112 and 114 stack to equal the transition region 109 dimension with cell heights CH3, CH2 and CH4, respectively. The transition region 109 spans cells 110, 112 and 114. The cell heights CH1, CH2, CH3 and CH4 can all be different or some can be different. The transition region 109 can be formed to transition one or more features with each of the cells 110, 112 and 114 from cell 102. Further, the features transitioned from the cell 102 to each of the cells 110, 112 and 114 can have a same or different features being transitioned. For example, metal lines could be transitioned between cell 102 and cell 110 while active regions can be transitioned between cell 102 and 114.

The transition region 109 can provide a transition between features of the cell 102 and the cells 110, 112 and 114. This can include transitioning geometric shapes of the features to permit for size or performance differences between the cells. The cell 102 can be located at any position along the boundary of the transition region 109. Here, the transition region 104 is rectangular in shape.

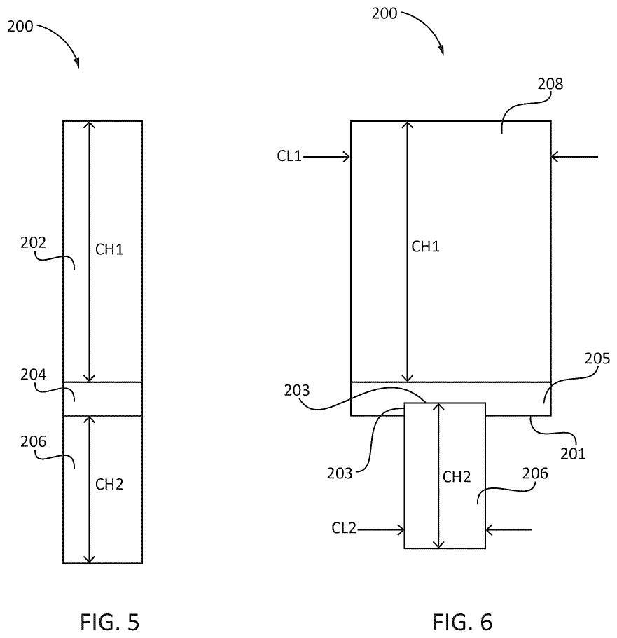

Referring to FIG. 5, devices and methods for manufacturing an integrated circuit 200 on a semiconductor device are shown in accordance with embodiments of the present invention. The integrated circuit 200 includes a plurality of cells that are configured to be placed in a manner that optimizes chip area, performance and any number of other parameters. A cell 202 includes a cell height CH1. A transition region 204 is adjacent to and borders cell 202. In this embodiment, the cell 202 and the transition region 204 share a cell width or cell length dimension. A cell 206 also borders the transition region 204 on a side opposite the cell 202. The cell 206 includes a different cell height CH2 that is not equal to CH1 of cell 202. The cell lengths of cell 202 and the cell 206 are aligned and different.

The transition region 204 can provide a transition between features of the cell 202 and the cell 206. This can include transitioning geometric shapes of the features to permit for size or performance differences between the cell 202 and cell 206. Here, the transition region 204 is rectangular in shape.

Referring to FIG. 6, the integrated circuit 200 includes a cell 208 with cell height CH1. A transition region 205 is adjacent to and borders cell 208. In this embodiment, the cell 208 and the transition region 205 share the cell width or length dimension. The cell 206 impinges on the transition region 205 and includes an extended border 203 on a side opposite the cell 208. The cell 206 includes a different cell height CH2 that is not equal to CH1 of cell 208. A cell length CL2 of the cell 206 can also be different than a cell length CL1 of cell 208.

The transition region 205 can provide a transition between features of the cell 208 and the cell 206. This can include transitioning geometric shapes of the features to permit for size or performance differences between the cell 208 and cell 206 through any side of the extended border 203. The cell 206 can be centered relative to cell 208 or be located at any position along the boundary of the transition region 205. Here, the transition region 205 is non-rectangular in shape.

Adjacent cells (not shown), e.g., on an east side and/or west side of the cell 206 can impinge upon the transition region 205 in a way similar to cell 206 or align with an outer border 201 of the transition region 205 (in a similar manner as cell 206 to transition region 204 in FIG. 5).

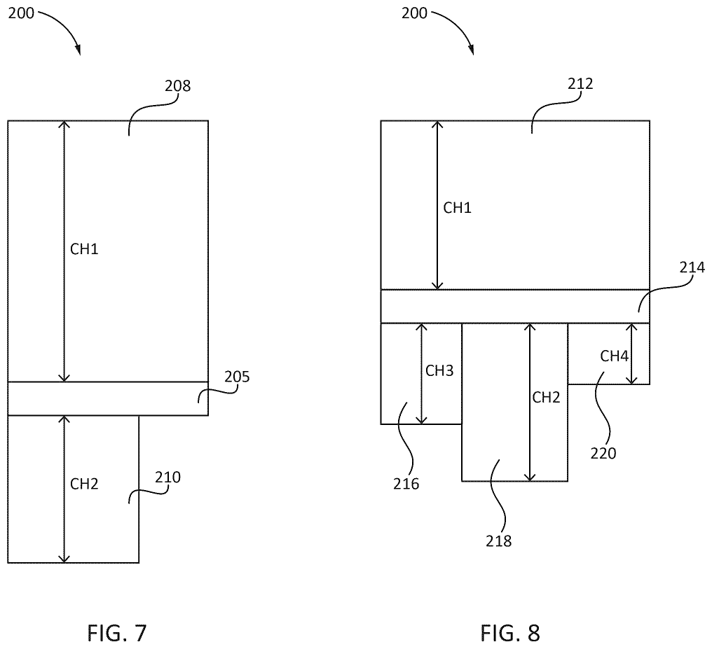

Referring to FIG. 7, the integrated circuit 200 includes a plurality of cells that are configured to be placed in a manner that optimizes chip area, performance and any number of other parameters. The cell 208 includes a cell height CH1. A transition region 205 is adjacent to and fully borders cell 208. A cell 210 also borders the transition region 205 on a side opposite the cell 208. In this embodiment, the cell 210 and the transition region 205 do not share a full border. The cell 210 includes a cell height CH2. The cell height CH2 of cell 210 is not equal to CH1 of cell 208. Cell lengths ca also be different. (See, e.g., FIG. 6).

The transition region 205 can provide a transition between features of the cell 208 and the cell 210. This can include transitioning geometric shapes of the features to permit for size or performance differences between the cell 208 and cell 210. The cell 210 can be aligned on an east or west end or be centered relative to cell 208 or be located at any position along the boundary of the transition region 205. Here, the transition region 205 is rectangular in shape.

Referring to FIG. 8, the integrated circuit 200 includes a cell 212 with cell height CH1. A transition region 214 is adjacent to and borders cell 212. In this embodiment, the cell 212 and the transition region 214 share a cell length or width dimension. Adjacent cells 216, 218 and 220 stack to equal the transition region 214 dimension with cell heights CH3, CH2 and CH4, respectively. The cell heights CH1, CH2, CH3 and CH4 can all be different or some can be different. The transition region 214 can be formed to transition one or more features within each of the cells 216, 218 and 220 and cell 212. Further, the features transitioned from the cell 212 to each of the cells 216, 218 and 220 can have a same or different features being transitioned. For example, metal lines could be transitioned between cell 212 and cell 216 while active regions can be transitioned between cell 212 and 220.

The transition region 214 can provide a transition between features of the cell 212 and the cells 216, 218 and 220. This can include transitioning geometric shapes of the features to permit for size or performance differences between the cells. The cell 212 can be located at any position along the boundary of the transition region 214. Here, the transition region 214 is rectangular in shape.

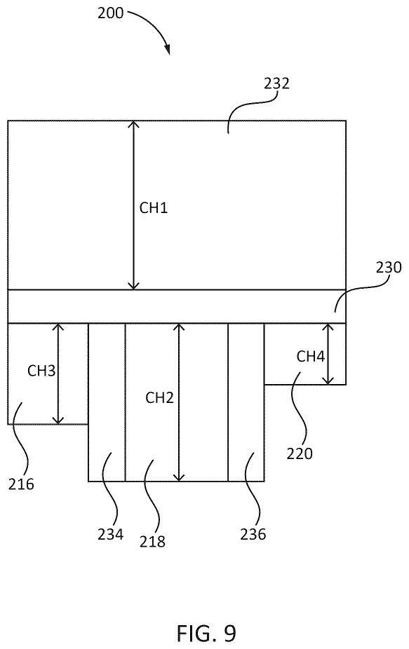

Referring to FIG. 9, the integrated circuit 200 includes a cell 232 with cell height CH1. A transition region 230 is adjacent to and borders cell 232. In this embodiment, the cell 232 and the transition region 230 share a cell length or width dimension. Adjacent cells 216, 218 and 220 include transition regions 234 and 236 therebetween. The cells 216, 218 and 220 and transition regions 234 and 236 stack to equal the transition region 230 dimension. The transition regions 230, 234 and 236 can be formed to transition one or more features within each of the cells 216, 218 and 220 and cell 232. Further, the features transition from the cell 232 to each of the cells 216, 218 and 220 and between the cells 216, 218 and 220 can have a same or different features being transitioned. For example, metal lines could be transitioned between cell 232 and cell 216 while active regions can be transitioned between cell 216 and 218.

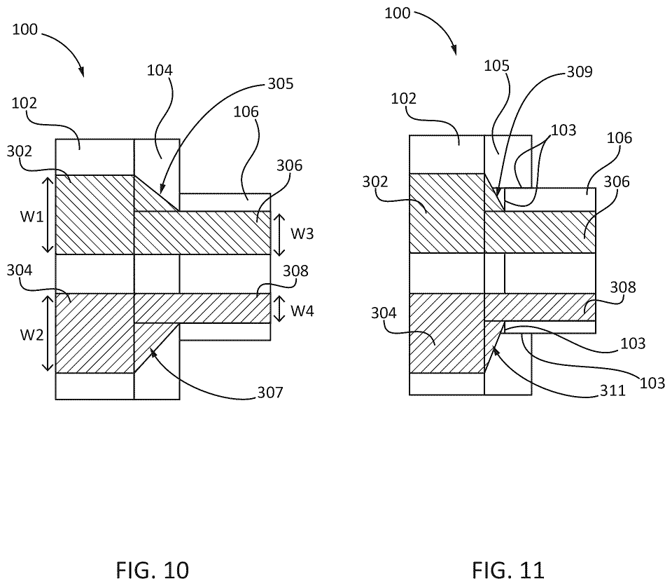

Referring to FIG. 10, in an embodiment, the integrated circuit 100 includes a plurality of cells that are configured to be placed in a manner that optimizes chip area, performance and any number of other parameters. The cell 102 (with cell height CH1) includes active regions 302 and 304. Active region 302 includes a width w1, and active region 304 includes a width w2. The cell 106 (with cell height CH2) includes active regions 306 and 308. Active region 306 includes a width w3, and active region 308 includes a width w4. The transition region 104 is adjacent to and borders cells 102 and 106.

The transition region 104 can provide a transition between features of the cell 102 and the cell 106. The features include active regions 302 and 304 of cell 102 and active regions 306 and 308 of cell 106. The transition region 104 includes transition shape 305 to provide a gradual transition between active region 302 of cell 102 and active region 306 in cell 106. The transition region 104 includes transition shape 307 to provide a gradual transition between active region 304 of cell 102 and active region 308 in cell 106. The transition shapes 305 and 307 include active region materials that are the same as the adjacent active regions. The transition shapes 305 and 307 can include non-rectangular shapes (e.g., triangles, trapezoids, parallelograms, rhombus, polygons, etc.).

Referring to FIG. 11, the integrated circuit 100 includes the cell 102 (with cell height CH1) and cell 106 (with cell height CH2). The transition region 105 is adjacent to and borders cell 102. The cell 106 impinges on the transition region 105, redefining a shape of the transition region 105. and includes the extended border 103 (FIG. 2) on a side opposite the cell 102.

The transition region 105 provides a more severe transition (than in FIG. 10) between features of the cell 102 and the cell 106. This can include transitioning geometric shapes of the features to permit for size or performance differences between the cell 102 and cell 106 through any side of the extended border 103. The cell 106 can be centered relative to cell 102 or be located at any position along the boundary of the transition region 105. Here, the transition region 105 includes non-rectangular shapes to make the transition between active regions 302 and 304 of cell 102 to active regions 306 and 308 of cell 106.

The transition region 105 includes transition shape 309 to provide a gradual transition between active region 302 of cell 102 and active region 306 in cell 106. The transition region 105 includes transition shape 311 to provide a gradual transition between active region 304 of cell 102 and active region 308 in cell 106. The transition shapes 309 and 311 can include active region materials that are the same as the adjacent active regions. The transition shapes 309 and 311 can include non-rectangular shapes (e.g., triangles, etc.).

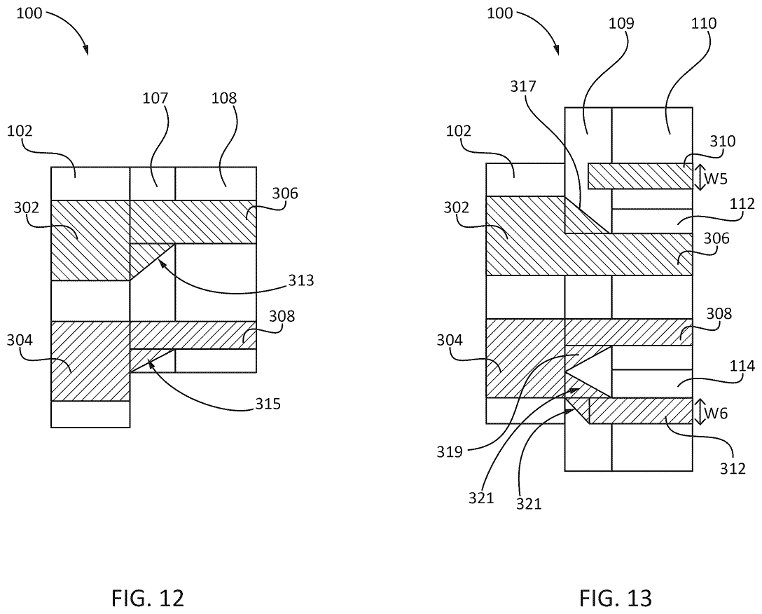

Referring to FIG. 12, the integrated circuit 100 includes the cell 102 (with cell height CH1) and cell 108 (e.g., each having a different cell height). The transition region 107 is adjacent to and borders cell 102. In this embodiment, the cell 102 and the transition region 107 do not share the cell height CH1 dimension. Instead, cell 108 and the transition region 107 share the cell height dimension. The transition region 107 includes transition shape 313 to provide a gradual transition between active region 302 of cell 102 and active region 306 in cell 108. The transition region 107 includes transition shape 315 to provide a gradual transition between active region 304 of cell 102 and active region 308 in cell 112. The transition shapes 313 and 315 include active region materials that are the same as the adjacent active regions. The transition shapes 313 and 315 can include non-rectangular shapes (e.g., triangles, etc.).

Referring to FIG. 13, the integrated circuit 100 includes the cell 102 (with cell height CH1) and cells 110, 112 and 114 (e.g., each having different cell heights). The transition region 109 is adjacent to and borders cell 102. In this embodiment, the cell 102 and the transition region 109 do not share the cell height CH1 dimension. Instead, adjacent cells 110, 112 and 114 stack to equal the transition region 109 dimension with cell heights CH3, CH2 and CH4, respectively (see FIG. 4). The transition region 109 transitions active regions with each of the cells 110, 112 and 114. An active region 310 of cell 110 terminates within the transition region 109.

The transition region 109 includes transition shape 317 to provide a gradual transition between active region 302 of cell 102 and active region 306 in cell 112. The transition region 109 includes transition shape 319 to provide a gradual transition between active region 304 of cell 102 and active region 308 in cell 112. The transition region 109 includes transition shapes 321 to also provide a gradual transition between active region 304 of cell 102 and an active region 312 in cell 114. The transition shapes 317, 319 and 321 include active region materials that are the same as the adjacent active regions. The transition shapes 317, 319 and 321can include non-rectangular shapes (e.g., triangles, etc.). The active region 310 includes a width w5 and active region 312 includes a width w6. The widths w5 and w6 can include any dimension.

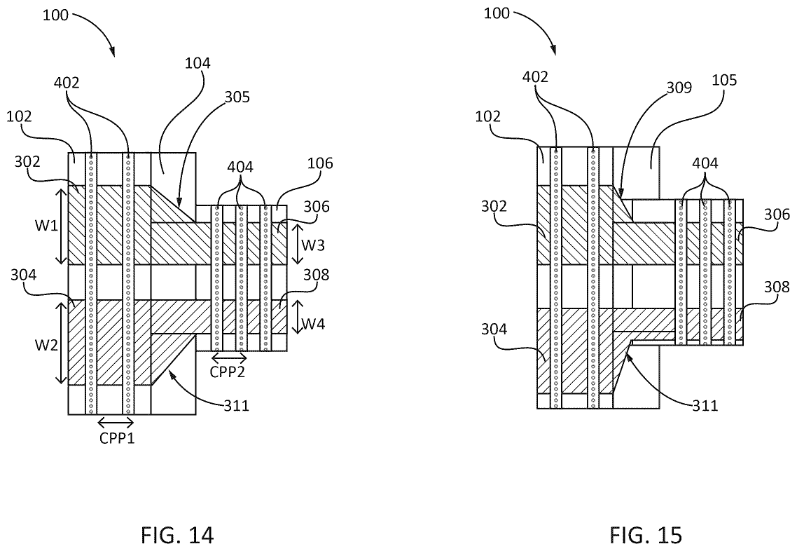

Referring to FIG. 14, in addition to or instead of the active region transition, the transition region 104 can provide a break between cells to provide different gate pitches (contacted gate poly pitch (CPP)). In an embodiment, the integrated circuit 100 includes gate lines 402 having a first gate pitch CPP1 for the cell 102 (with cell height CH1) on a first side of the transition region 104, and gate lines 404 having a second gate pitch CPP2 on a second side of the transition region 104. The transition region 104 does not include any gate structures, but gate structures can be transitioned through the transition region 104 if the gate structure runs transversely to the transition region 104 (e.g., perpendicular to the direction of gate lines 402, 404 as depicted in FIG. 13).

Referring to FIG. 15, in addition to or instead of the active region transition, the transition region 105 can provide a break between cells to provide different gate pitches. In an embodiment, the integrated circuit 100 includes gate lines 402 having the first gate pitch CPP1 for the cell 102 (with cell height CH1) on a first side of the transition region 105, and gate lines 404 having the second gate pitch CPP2 on a second side of the transition region 105. The transition region 105 does not include any gate structures, but gate structures can be transitioned through the transition region 105 if the gate structure runs transversely to the transition region 105 (e.g., perpendicular to the direction of gate lines 402, 404 as depicted in FIG. 15).

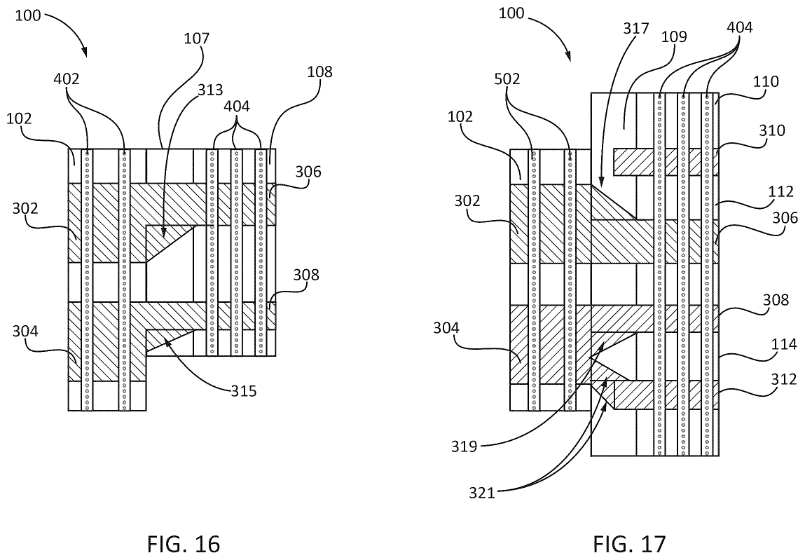

Referring to FIG. 16, in addition to or instead of the active region transition, the transition region 107 can provide a break between cells to provide different gate pitches. In an embodiment, the integrated circuit 100 includes gate lines 402 having a first gate pitch CPP1 for the cell 102 (with cell height CH1) on a first side of the transition region 107. Gate lines 404 have a second gate pitch CPP2 on a second side of the transition region 107 for cell 108. The transition region 107 does not include any gate structures, but gate structures can be transitioned through the transition region 107 if the gate structures run transversely to the transition region 107 (e.g., perpendicular to the direction of gate lines 402, 404 as depicted in FIG. 16).

Referring to FIG. 17, in addition to or instead of the active region transition, the transition region 109 can provide a break between cells to provide different gate pitches. In an embodiment, the integrated circuit 100 includes gate lines 402 having a first gate pitch CPP1 for the cell 102 (with cell height CH1) on a first side of the transition region 109. Gate lines 404 having a second gate pitch CPP2 on a second side of the transition region 109 are common to cells 110, 112 and 114. The transition region 109 does not include any gate structures, but gate structures can be transitioned through the transition region 109 if the gate structures run transversely to the transition region 109 (e.g., perpendicular to the direction of gate lines 402, 404 as depicted in FIG. 17).

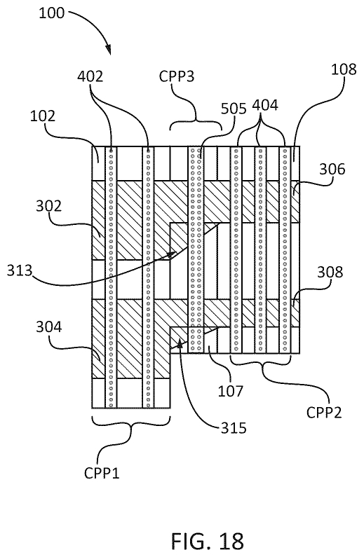

Referring to FIG. 18, in an embodiment, one or more gates 505 can be present in the transition region 104. For example, a first gate pitch CPP1 can be present on one side of the transition region 104 and a second gate pitch CPP2 can be present on the other side of the transition region 104. One or more gates 505 can be provided in the transition region 104 to result in an intermediate CPP3 between CPP1 and CPP2. A gate can also be different in some embodiments.

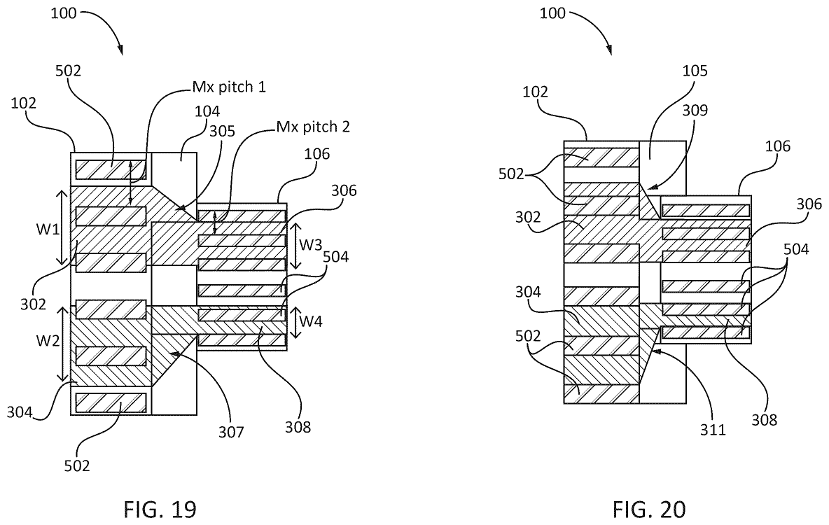

Referring to FIG. 19, in addition to or instead of the active region transition and gate pitch transitions, the transition region 104 can provide a break between cells to provide different metal line pitches (Mx pitch). Note that the gate lines 402 and 404 have been omitted for viewing clarity. In an embodiment, the integrated circuit 100 includes metal lines 502 in a metal layer x having a first metal line pitch Mx pitch 1 for the cell 102 (with cell height CH1) on a first side of the transition region 104. Metal lines 504 have a second metal line pitch Mx pitch 2 on a second side of the transition region 104. In the embodiment, the transition region 104 does not include any metal line structures; however, transition connections can be made in a similar fashion as active regions to make connections through the transition region 104 to connect metal lines 502 with metal lines 504 across and through the transition region 104. It should be understood that, in other embodiments, the metal lines can be aligned orthogonally to metal lines 502 and 504 and be included or omitted from the transition region 104.

Referring to FIG. 20, in addition to or instead of the active region transition and gate pitch transitions, the transition region 105 can provide a break between cells to provide different metal line pitches (Mx pitch). Note that the gate lines 402 and 404 have been omitted for viewing clarity. In an embodiment, the integrated circuit 100 includes metal lines 502 in a metal layer x having a first metal line pitch Mx pitch 1 for the cell 102 (with cell height CH1) on a first side of the transition region 105. Metal lines 504 have a second metal line pitch Mx pitch 2 on a second side of the transition region 105. In the embodiment, the transition region 105 does not include any metal line structures; however, transition connections can be made in a similar fashion as active regions to make connections through the transition region 105 to connect metal lines 502 with metal lines 504 across and through the transition region 105. It should be understood that, in other embodiments, the metal lines can be aligned orthogonally to metal lines 502 and 504 and be included or omitted from the transition region 105.

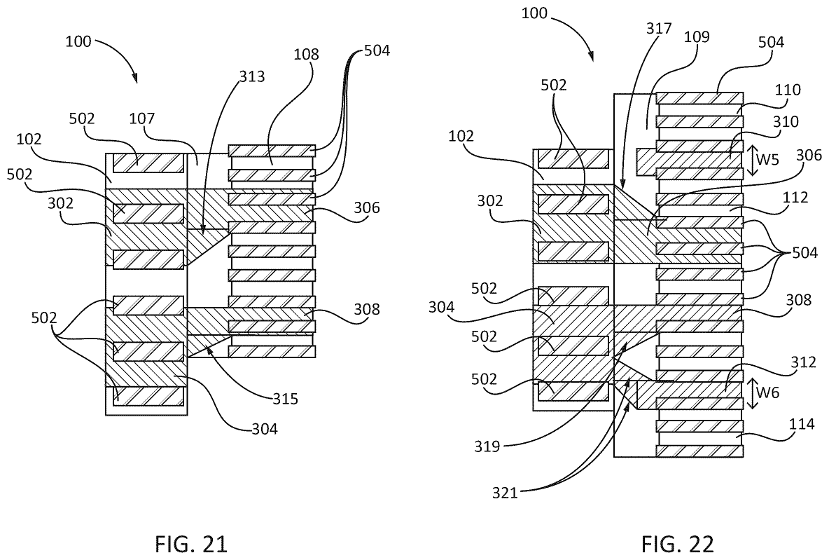

Referring to FIG. 21, in addition to or instead of the active region transition and gate pitch transitions, the transition region 107 can provide a break between cells to provide different metal line pitches. Note that the gate lines 402 and 404 have been omitted for viewing clarity. In an embodiment, the integrated circuit 100 includes metal lines 502 in a metal layer x having a first metal line pitch Mx pitch 1 for the cell 102 on a first side of the transition region 105. Metal lines 504 have a second metal line pitch Mx pitch 2 on a second side of the transition region 107. In the embodiment, the transition region 107 does not include any metal line structures; however, transition connections can be made in a similar fashion as active regions to make connections through the transition region 107 to connect metal lines 502 with metal lines 504 across and through the transition region 107. It should be understood that, in other embodiments, the metal lines can be aligned orthogonally to metal lines 502 and 504 and be included or omitted from the transition region 107.

Referring to FIG. 22, in addition to or instead of the active region transition and gate pitch transitions, the transition region 109 can provide a break between cells to provide different metal line pitches. Note that the gate lines 402 and 404 have been omitted for viewing clarity. In an embodiment, the integrated circuit 100 includes metal lines 502 in a metal layer x having a first metal line pitch Mx pitch 1 for the cell 102 on a first side of the transition region 109. Metal lines 504 have a second metal line pitch Mx pitch 2 on a second side of the transition region 109.

In the embodiment, the transition region 109 does not include any metal line structures; however, transition connections can be made in a similar fashion as active regions to make connections through the transition region 109 to connect metal lines 502 with metal lines 504 across and through the transition region 107. It should be understood that, in other embodiments, the metal lines can be aligned orthogonally to metal lines 502 and 504 and be included or omitted from the transition region 109. Metal lines 504 are common to cells 110, 112 and 114.

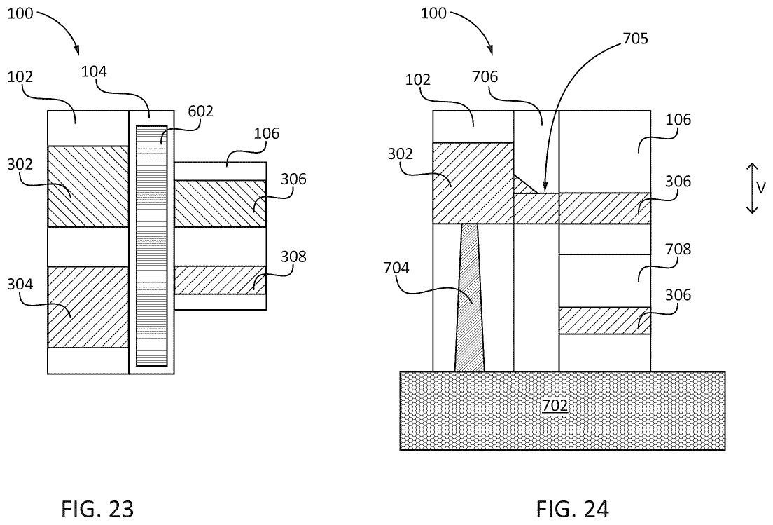

Referring to FIG. 23, in an embodiment, the integrated circuit 100 includes a plurality of cells that are configured to be placed in a manner that optimizes chip area, performance and any number of other parameters. The transition region 104 includes a diffusion break 602 that can provide an electrical break between features of the cell 102 and the cell 106. The features separated by the diffusion break 602 can include active regions 302 and 304 of cell 102 and active regions 306 and 308 of cell 106. In some embodiments, the diffusion break 602 can include multiple diffusion breaks.

Referring to FIG. 24, a partial cross-sectional view of the integrated circuit 100 is shown in accordance with an embodiment. A transition region 706 provides a transition between cell 102 and cell 106 in a vertical direction V. In an example, the active region 302 of cell 102 includes a transition shape 705 to transition to active region 306 in cell 106. This represents a transition in active region thicknesses. The transition can be made relative to a backside of the integrated circuit 100 or relative to a frontside of the integrated circuit 100. Cell 106 can be stacked on a cell 708. A backside interconnect layer 702 can connect to one or more components of the cells and or the transition region 706 using one or more contacts 704.

In some embodiments, multiple features may be transitioned concurrently or individually within the transition region between cells of different heights. The transition region may accommodate changes in various features, including but not limited to active region dimensions, gate structures, metallization layers, diffusion regions, etc. For example, the transition region may include a gradual change in active region width, transitioning from a wider active region in one cell to a narrower active region in an adjacent cell. Concurrently or individually, the transition region may also incorporate changes in gate pitch, allowing for a smooth transition between cells with different gate densities. Metallization layers may also be transitioned within the same region. This may include adjusting metal line widths, pitches, or even the number of metal layers between cells of different heights. In some cases, the transition region may include tapering of metal lines or the introduction of additional vias to manage the change in metallization patterns. Diffusion regions may be another feature that can be transitioned within these regions. The transition may involve changes in dopant concentrations, diffusion depths, or the overall shape and size of diffusion areas between cells.

In some implementations, the transition of features may be coordinated to optimize performance and maintain signal integrity. For instance, changes in active region dimensions may be coordinated with adjustments in gate structures to ensure proper device operation across the transition. The order and manner in which these features are transitioned may vary depending on the specific design requirements and manufacturing processes.

Additionally, the transition region may accommodate changes in cell height by adjusting the vertical dimensions of various features. This may include tapering of vertical structures, such as fins in FinFET (fin field effect transistors) designs, or adjusting the thickness of dielectric layers between different cell heights. By allowing for the transition of multiple features, either together or separately, the transition region may serve as a versatile interface between cells of different heights, enabling more complex and efficient integrated circuit designs.

It should be understood that the layouts of FIGS. 9-21 showing cells disposed on east/west sides of the transition region can be applied to transition regions with cells of north/south boundaries as depicted in FIGS. 5-8. Further, transition regions can include transitions in a vertical orientation, e.g., on sides or above/below as depicted in FIG. 22.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or backside interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment,” as well as other variations thereof, means that a particular feature, structure, characteristic, and so forth described in connection with the embodiment is included in at least one embodiment. Thus, the appearances of the phrase “in one embodiment” or “in an embodiment,” as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent, by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. An integrated circuit, comprising:
a first cell of a first cell height having a first feature;
a second cell of a second cell height having a second feature corresponding to the first feature, the first cell height being greater than the second cell height; and
a transition region bordering the first cell and the second cell, the transition region including a change in dimension between the first feature and the second feature.

2. The integrated circuit of claim 1, wherein the first cell has a first cell length, and the second cell has a second cell length, the first cell length being unequal to the second cell length.

3. The integrated circuit of claim 1, wherein the first feature is a first active region width, and the second feature is a second active region width.

4. The integrated circuit of claim 1, wherein the first feature is a first active region thickness, and the second feature is a second active region thickness.

5. The integrated circuit of claim 1, wherein the first feature is a first gate pitch, and the second feature is a second gate pitch.

6. The integrated circuit of claim 1, wherein the first feature is a first metal line pitch, and the second feature is a second metal line pitch.

7. The integrated circuit of claim 1, wherein the transition region is formed on a backside of the integrated circuit.

8. The integrated circuit of claim 1, wherein the transition region is non-rectangular.

9. The integrated circuit of claim 1, wherein the transition region includes a diffusion break.

10. The integrated circuit of claim 1, wherein the transition region spans multiple cells of different cell heights.

11. An integrated circuit, comprising:
a first cell of a first cell height having a first active region width;
a second cell of a second cell height having a second active region width, the first cell height being greater than the second cell height; and
a transition region bordering the first cell and the second cell, the transition region at least partially including a non-rectangular transition shape to transition a change in dimension between the first active region width and the second active region width.

12. The integrated circuit of claim 11, wherein the first cell has a first cell length, and the second cell has a second cell length, the first cell length being unequal to the second cell length.

13. The integrated circuit of claim 11, wherein the first cell includes a first gate pitch, and the second cell includes a second gate pitch, the transition region transitioning between the first gate pitch and the second gate pitch.

14. The integrated circuit of claim 11, wherein the first cell includes a first metal line pitch, and the second cell includes a second metal line pitch, the transition region transitioning between the first metal line pitch and the second metal line pitch.

15. The integrated circuit of claim 11, wherein the transition region is formed from a backside of the integrated circuit.

16. The integrated circuit of claim 11, wherein at least one of the first cell or the second cell is connected to a backside metallization layer.

17. The integrated circuit of claim 11, wherein the transition region spans multiple cells of different cell heights.

18. The integrated circuit of claim 11, further comprising a diffusion break within the transition region.

19. An integrated circuit, comprising:
a first cell of a first cell height having a first feature;
a second cell of a second cell height having a second feature, the first cell height being greater than the second cell height;
a third cell having a third feature; and
a transition region bordering the first cell, the second cell and the third cell, the transition region at least partially including transition shapes to transition a change in dimension between at least two of the first feature, the second feature and the third feature.

20. The integrated circuit of claim 19, wherein the first feature, the second feature and the third feature include at least one of a cell length, an active region width, a gate pitch and/or a metal line pitch.
